(19) United States
(12) Patent Application Publication
(10) Pub. No.: US 2013/0332803 A1
(43) Pub. Date: Dec. 12, 2013

(54) TRANSMITTING AND RECEIVING SYSTEM, TRANSMITTING AND RECEIVING METHOD, AND COMPUTER READABLE MEDIUM

(71) Applicant: FUJI XEROX CO., LTD., Tokyo (JP)

(72) Inventor: Tsutomu HAMADA, Kanagawa (JP)

(73) Assignee: FUJI XEROX CO., LTD., Tokyo (JP)

(21) Appl. No.: 13/773,139

(22) Filed: Feb. 21, 2013

(30) Foreign Application Priority Data
Jun. 6, 2012 (JP) 2012-128688

(51) Int. Cl. H03M 13/05

(52) U.S. Cl. CPC H03M 13/05
USPC 714/776

(57) ABSTRACT

A transmitting and receiving system includes a first transmitting and receiving apparatus including a generating unit that generates a transmission packet by adding an error correction code to data which are to be transmitted and are subjected to a bit number conversion, wherein a code that detects or corrects, in the case where a single-bit error occurs, the single-bit error is used as information bits contained in a header of the transmission packet, and the code is used when a bit error uncorrectable by the error correction code occurs due to transmission during transmission of the transmission packet, and a transmitting unit that transmits the transmission packet.

### CROSS-REFERENCE TO RELATED APPLICATIONS

This application is based on and claims priority under 35 USC 119 from Japanese Patent Application No. 2012-128688 filed Jun. 6, 2012.

### BACKGROUND

(i) Technical Field

The present invention relates to a transmitting and receiving system, a transmitting and receiving method, and a computer readable medium.

(ii) Related Art

There is known a system that detects an error occurred during transmission using a cyclic redundancy check (CRC) code as an error-detecting code, transmits as a reception response a positive acknowledgement (ACK) when reception is successful, and transmits a negative acknowledgement (NAK) when an error is detected.

### SUMMARY

According to an aspect of the invention, there is provided a transmitting and receiving system that includes a first transmitting and receiving apparatus including a generating unit that generates a transmission packet by attaching an error correction code to data to be transmitted, the data being subjected to a bit number conversion, wherein a code that detects or corrects, in the case where a single-bit error occurs, the single-bit error is used as information bits contained in a header of the transmission packet, the code being used when a bit error uncorrectable by the error correction code occurs due to transmission during transmission of the transmission packet, and a transmitting unit that transmits the transmission packet.

### BRIEF DESCRIPTION OF THE DRAWINGS

Exemplary embodiments of the present invention will be described in detail based on the following figures, wherein:

FIG. 1 is a block diagram showing an exemplary configuration of a transmitting and receiving system according to a first exemplary embodiment of the present invention;

FIG. 2 is a block diagram showing an exemplary configuration of a transmit packet according to the first exemplary embodiment;

FIG. 3 is a diagram showing an exemplary configuration of a retransmission request packet according to the first exemplary embodiment;

FIG. 4A is a diagram showing patterns after 8B10B inverse conversion corresponding to 10 error patterns;

FIG. 4B is a diagram showing patterns obtained by 8B10B inverse conversion, which correspond to 10 error patterns;

FIG. 4C is a diagram showing patterns obtained by 8B10B inverse conversion, which correspond to 10 error patterns;

FIG. 4D is a diagram showing patterns obtained by 8B10B inverse conversion, which correspond to 10 error patterns;

FIG. 4E is a diagram showing patterns obtained by 8B10B inverse conversion, which correspond to 10 error patterns;

FIG. 4F is a diagram showing patterns obtained by 8B10B inverse conversion, which correspond to 10 error patterns;

FIG. 4G is a diagram showing patterns obtained by 8B10B inverse conversion, which correspond to 10 error patterns;

FIG. 4H is a diagram showing patterns obtained by 8B10B inverse conversion, which correspond to 10 error patterns;

FIG. 5 is a table showing the relationship between transmission data and reception data in the error patterns of FIGS. 4A and 4D.

FIG. 6A illustrates exemplary operations of a second transmitting and receiving apparatus in a normal mode;

FIG. 6B illustrates exemplary operations of the second transmitting and receiving apparatus in a retransmission mode;

FIG. 7 is a diagram illustrating an exemplary configuration of a transmitting and receiving system according to a second exemplary embodiment of the present invention;

FIGS. 8A and 8B illustrate exemplary configurations of response packets generated by a response packet generating unit of the second transmitting and receiving apparatus, wherein FIG. 8A illustrates a positive acknowledgement (ACK) and FIG. 8B illustrates a negative acknowledgement (NAK);

FIG. 9 is a diagram illustrating an exemplary configuration of a transmit packet generated by a transmit packet generating unit of a transmitting and receiving system according to a third exemplary embodiment of the present invention; and

FIG. 10 is a diagram illustrating an exemplary configuration of a transmit packet generated by a transmit packet generating unit of a transmitting and receiving system according to a fourth exemplary embodiment of the present invention.

### DETAILED DESCRIPTION

Hereinafter, exemplary embodiments of the present invention will be described with reference to the accompanying drawings. It is to be noted that the components having the substantially same functions are denoted by the same reference numerals, and the same description will not be repeated.

### First Exemplary Embodiment

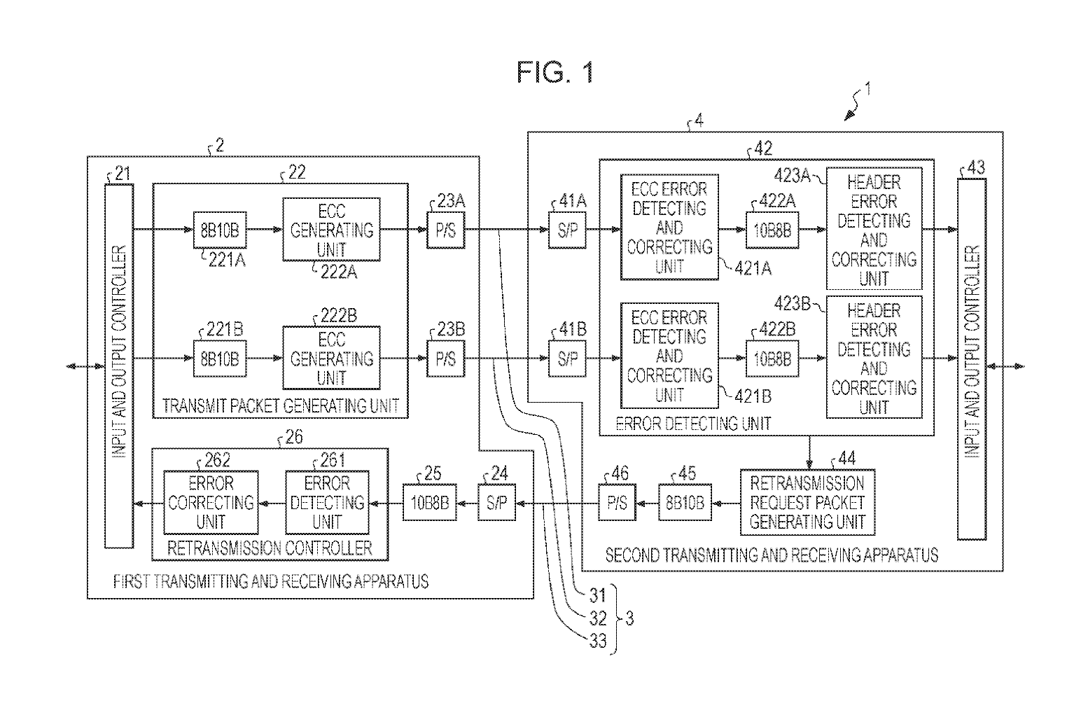

FIG. 1 is a block diagram showing an exemplary configuration of a transmitting and receiving system 1 according to a first exemplary embodiment of the present invention. As illustrated in FIG. 1, this transmitting and receiving system 1 includes a first transmitting and receiving apparatus 2 and a second transmitting and receiving apparatus 4, which are connected through a transmission path 3 so as to serially transmit and receive information. The transmission path 3 includes a first lane 31, a second lane 32, and a third lane 33.

(Configuration of First Transmitting and Receiving Apparatus)

As illustrated in FIG. 1, the first transmitting and receiving apparatus 2 includes an input and output controller 21, a transmit packet generating unit 22 provided to correspond to the first lane 31 and the second lane 32, and parallel-to-serial converters (P/S) 23A and 23B which are provided to respectively correspond to the first lane 31 and the second lane 32. The first transmitting and receiving apparatus 2 further includes a serial-to-parallel converter (S/P) 24, a 10B8B converter (10B8B) 25, and a retransmission controller 26, each of which is provided to correspond to the third lane 33. It is to be noted that the transmit packet generating unit 22 is an example of a generating unit. The parallel-to-serial converters 23A and 23B are examples of a transmitting unit. The serial-to-parallel converter 24 and the 10B8B converter 25 are examples of a receiving unit.

(Configuration of Second Transmitting and Receiving Apparatus)

As illustrated in FIG. 1, the second transmitting and receiving apparatus 4 includes serial-to-parallel converters (S/P) 41A and 41B, which are provided to respectively correspond to the first lane 31 and the second lane 32, an error detecting unit 42, and an input and output controller 43, each of which is provided to correspond to the first lane 31 and the second lane 32. The second transmitting and receiving apparatus 4 further includes a retransmission request packet generating unit 44, an 8B10B converter (8B10B) 45, and a parallel-to-serial converter (P/S) 46, each of which is provided to correspond to the third lane 33. It is to be noted that the serial-to-parallel converters 41A and 41B are examples of a receiving unit. The 8B10B converter 45 and the parallel-to-serial converter 46 are examples of a transmitting unit.

(Transmission Path)

In this exemplary embodiment, an electric cable for transmitting electrical signals is used as the transmission path 3. However, an optical cable for transmitting optical signals may alternatively be used. In the case of using an optical cable, a photoelectric converter needs to be provided in each of the transmitting end and receiving end. Each of the lanes 31, 32, and 33 of the transmission path 3 includes two transmission lines, and may be a differential line for transmitting differential signals. The number of lanes included in the transmission path 3 is not limited to three.

(Configuration of Components of First Transmitting and Receiving Apparatus)

The input and output controller 21 of the first transmitting and receiving apparatus 2 exchanges data with a reproduction apparatus, for example. The input and output controller 43 of the second transmitting and receiving apparatus 4 exchanges data with a video display apparatus, for example. Further, the input and output controller 21 of the first transmitting and receiving apparatus 2 includes a transmission buffer (not shown) that holds transmitted data for a predetermined time period. It is to be noted that the transmission buffer may hold transmitted data until a positive acknowledgement (ACK) is received. Data exchange may be performed not only between the reproduction apparatus and the video display apparatus, but also between an image information generating apparatus and an image forming apparatus.

The transmit packet generating unit 22 includes 8B10B converters (8B10B) 221A and 221B and ECC generating units 222A and 222B, which are provided to correspond to the first lane 31 and the second lane 32, and generates a transmit packet by putting data to be transmitted (transmission data) (e.g., image information) into a packet. The transmit packet will be described below in greater detail. The transmit packet is an example of a transmission packet.

The transmit packet generating unit 22 puts data of a fixed length (e.g., 100 bytes) to be transmitted into a packet by attaching a header and an ECC (described below) thereto.

Each of the 8B10B converters 221A and 221B performs, as a bit number conversion, an 8B10B conversion on 8-bit data using a conversion table so as to output data in units of 10 bits. The 8B10B conversion is configured to adjust the DC balance such that the transmission data contain the moderate amount of 0s and 1s. A scheme known as 8B10B conversion adjusts the DC balance by converting data of 8 bits into data of 10 bits having a predetermined ratio of 0s to 1s, which is close to 50%.

Each of the ECC generating units 222A and 222B performs an error correction coding (ECC) operation, and generates a transmit packet by attaching the obtained ECC to the data to be transmitted. The ECC is an encoding technique that transmits transmission data with a redundant bit attached thereto such that the receiving end can perform an error detection so as to determine whether the received data are correct, and correct an error if the error is correctable. In the exemplary embodiments of the present invention, well-known ECCs such as Hamming codes and Reed-Solomon codes may be used. The ECC is an example of an error correction code.

Each of the parallel-to-serial converters 23A and 23B is configured to convert parallel data to serial data (P/S conversion) and send the converted data, and includes a register for setting a de-emphasis that attenuates direct-current components of the signal waveform, a pre-emphasis that emphasizes high-frequency components of the signal waveform, a differential voltage, and the like, as the initial settings upon power-on.

The serial-to-parallel converter 24 is configured to convert serial data to parallel data (S/P conversion), and includes a register for setting an equalizer that compensates for degradation of the signal waveform occurred in the transmission path 3 and the like, as the initial settings upon power-on.

The 10B8B converter 25 performs, as an inverse conversion of the number of bits, an 8B10B inverse conversion (10B8B conversion) on 10-bit data using a conversion table so as to output data in units of 8 bits.

The retransmission controller 26 instructs the input and output controller 21 to perform a retransmission in response to a retransmission request packet transmitted from the second transmitting and receiving apparatus 4 to the first transmitting and receiving apparatus 2.

(Configuration of Components of Second Transmitting and Receiving Apparatus)

Each of the serial-to-parallel converters 41A and 41B has the same configuration as the serial-to-parallel converter 24 of the first transmitting and receiving apparatus 2, and is configured to convert serial data to parallel data (S/P conversion).

The error detecting unit 42 includes ECC error detecting and correcting units 421A and 421B, 10B8B converters (10B8B) 422A and 422B, and header error detecting and correcting units 423A and 423B, which are provided to correspond to the first lane 31 and the second lane 32.

Each of the ECC error detecting and correcting units 421A and 421B extracts data from a transmit packet transmitted from the first transmitting and receiving apparatus 2, performs an ECC check, and reports the ECC check results to the retransmission request packet generating unit 44. More specifically, if there is no ECC error or if there is an ECC error of two or more bits, each of the ECC error detecting and correcting units 421A and 421B outputs data as they are to the subsequent stage. If there is a single-bit ECC error, each of the ECC error detecting and correcting units 421A and 421B outputs data to the subsequent stage after performing an error correction. The ECC error detecting and correcting units 421A and 421B are examples of a correcting unit.

Each of the 10B8B converters 422A and 422B performs, as an inverse conversion of the number of bits, an 8B10B inverse conversion (10B8B conversion) on 10-bit data using a conversion table so as to output data in units of 8 bits.

Each of the header error detecting and correcting units 423A and 423B performs a header check so as to determine whether there is an error with a header 110, and reports the header check results to the retransmission request packet generating unit 44. The header check results contain information indicating the presence or absence of an error, the error type (ID error, NIT error), and the data type. More specifically, each of the header error detecting and correcting units 423A and 423B performs an error correction if there is a single-bit error in the header 110, outputs data to the subsequent stage if the data are image information, discards data if the data are information other than image information, and switches the mode to a retransmission mode if there is a not-in-table (NIT) error. The “NIT error” as used herein refers to an error indicating that data are not present in an 8B10B conversion table. The header error detecting and correcting units 423A and 423B are examples of a correcting unit.

The retransmission request packet generating unit 44 is configured to, on the basis of the ECC check results reported from the ECC error detecting and correcting units 421A and 421B and the header check results reported from the header error detecting and correcting units 423A and 423B, switch the mode to the retransmission mode if the ECC error is in two or more bits and if the header 110 has a NIT error, and generate a retransmission request packet and transmit the retransmission request packet to the first transmitting and receiving apparatus 2 if the header 110 has an error other than a NIT error and if the data are information other than image information. The retransmission request packet contains a header indicating that the packet is a retransmission request, and a sequence ID of data whose retransmission is requested. The retransmission request packet will be described below in greater detail. The retransmission request packet generating unit 44 is an example of a generating unit. The retransmission request packet is an example of a response packet.

The 8B10B converter 45 performs, as a bit number conversion, an 8B10B conversion on 8-bit data using a conversion table so as to output data in units of 10 bits.

The parallel-to-serial converter 46 has the same configuration as the parallel-to-serial converters 23A and 23B of the first transmitting and receiving apparatus 2, and is configured to convert parallel data to serial data (P/S conversion) and send the converted data.

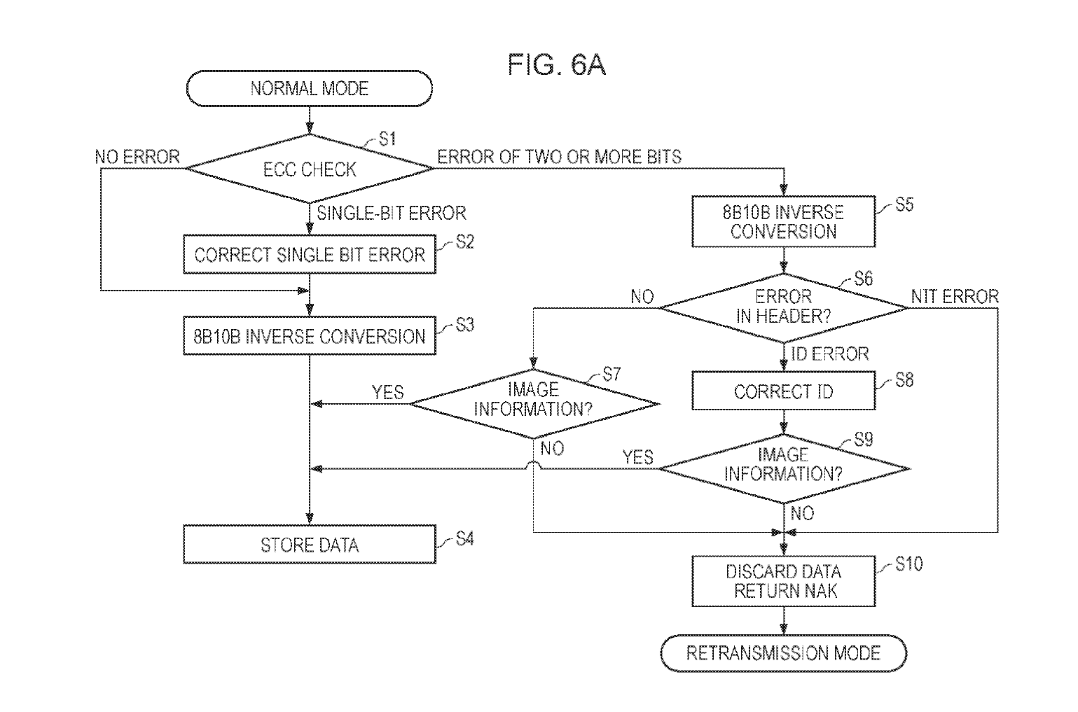

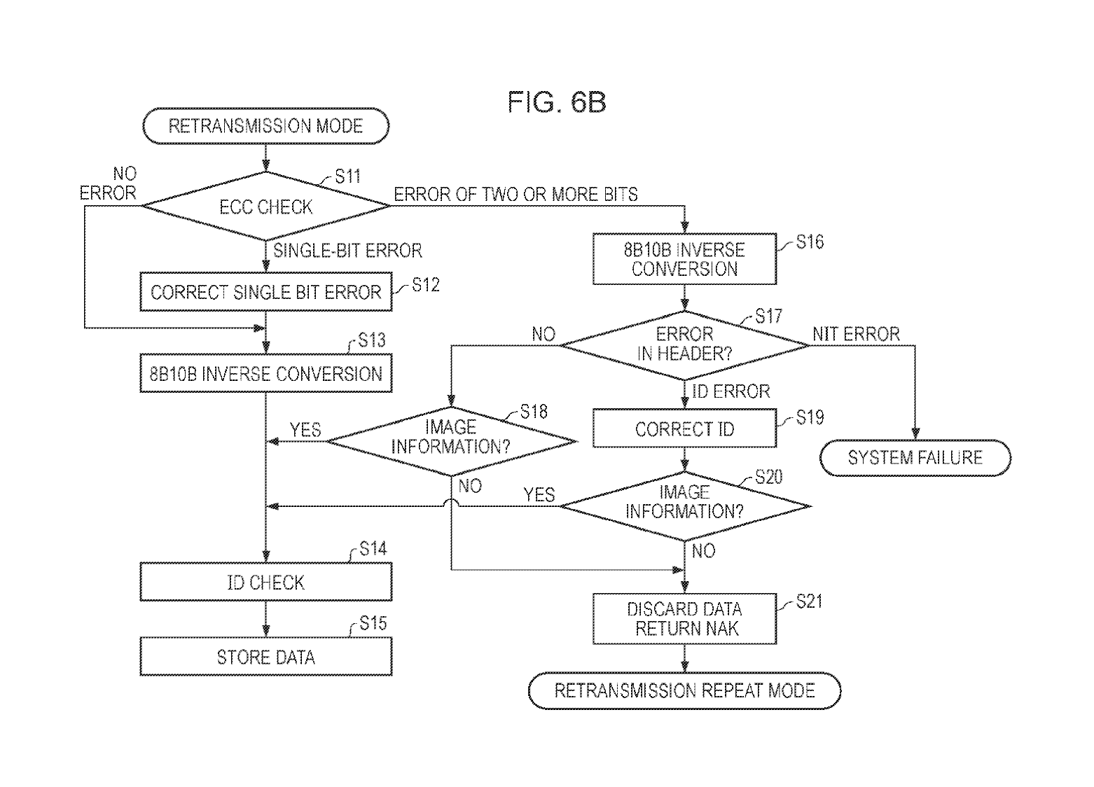

Part or all of the elements of each of the first and second transmitting and receiving apparatuses 2 and 4 may be formed of hardware circuits such as a field programmable gate array (FPGA) and an application specific integrated circuit (ASIC). Alternatively, the elements of the first and second transmitting and receiving apparatuses 2 and 4 may be realized by a CPU operating in accordance with a program illustrated in FIG. 6 (describe below) on the respective computers in the first and second transmitting and receiving apparatuses 2 and 4.

(Structure of Transmit Packet)

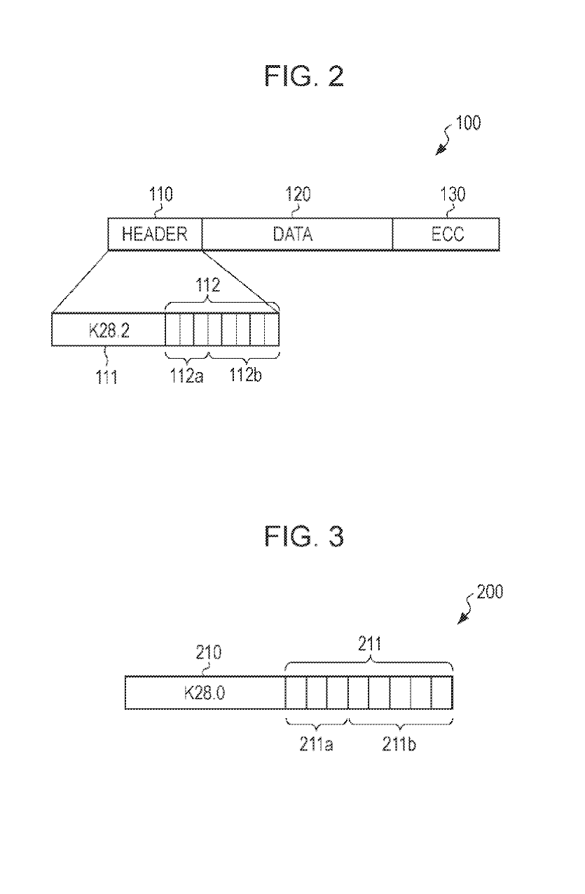

FIG. 2 is an exemplary configuration of a transmit packet 100 generated by the transmit packet generating unit 22 of the first transmitting and receiving apparatus 2. The transmit packet 100 has a fixed length, and contains a header 110 of two bytes, data 120 of 256 bytes, and an ECC 130 of two bytes, for example. The header 110 contains a start packet 111 including a K-code (e.g., K28.2) which indicates the start of the transmit packet 100, and an identification information item 112 of 8 bits. The higher-order 3 bits of the identification information item 112 store data identification information 112a, and the lower-order 5 bits store a sequence ID 112b. In the case where a single-bit error due to transmission occurs during transmission of the transmit packet 100, the data identification information 112a makes it possible to detect or correct the error. As the data identification information 112a, codes (e.g., “000” and “011”) that make it possible to distinguish between the types of data, namely, image information and information other than image information are used. If the data identification information 112a is “000”, the data 120 are image information. If the data identification information 112a is “011”, the data 120 are information other than image information. As the sequence ID 112b, codes that make it possible to detect a single-bit error occurred due to transmission during transmission of the transmit packet 100 are used. The sequence ID 112b is an example of identification information of the transmit packet 100.

(Structure of Retransmission Request Packet)

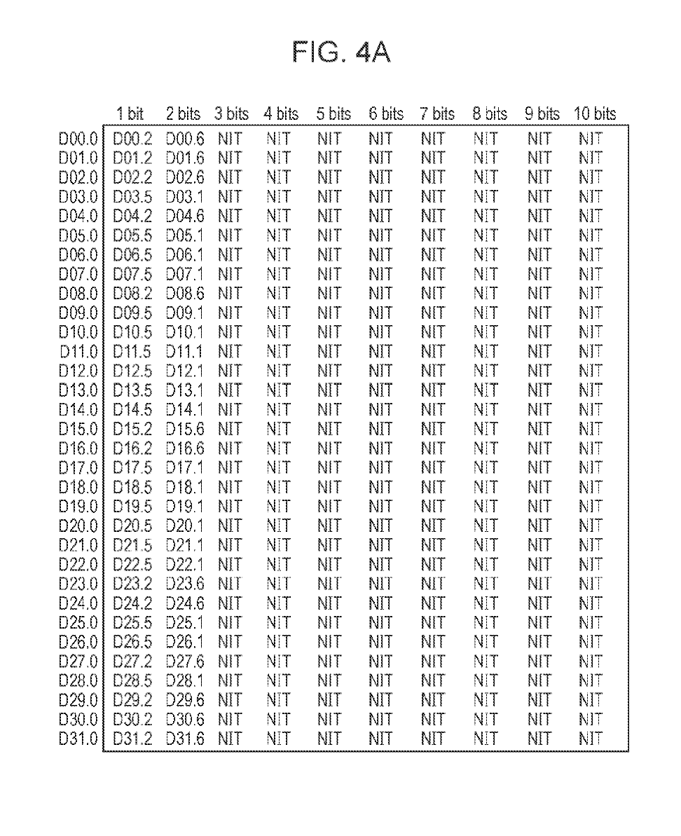

FIG. 3 is an exemplary configuration of a retransmission request packet 200 generated by the retransmission request packet generating unit 44 of the second transmitting and receiving apparatus 4. The retransmission request packet 200 contains a start packet 210 including a K-code (e.g., K28.0) which indicates the start of the retransmission request packet 200, and a response information item 211. The response information item 211 includes a negative acknowledgement (NAK) 211a of 3 bits, and a sequence ID 211b of 5 bits. As the negative acknowledgement (NAK) 211a, codes (e.g., “000” and “011”) that make it possible to detect or correct a single-bit error occurred due to transmission during transmission of the retransmission request packet 200 are used. As the sequence ID 211b of the retransmission request packet 200, the same ID as the sequence ID 112b of the corresponding transmit packet 100 is used.

(Error Patterns)

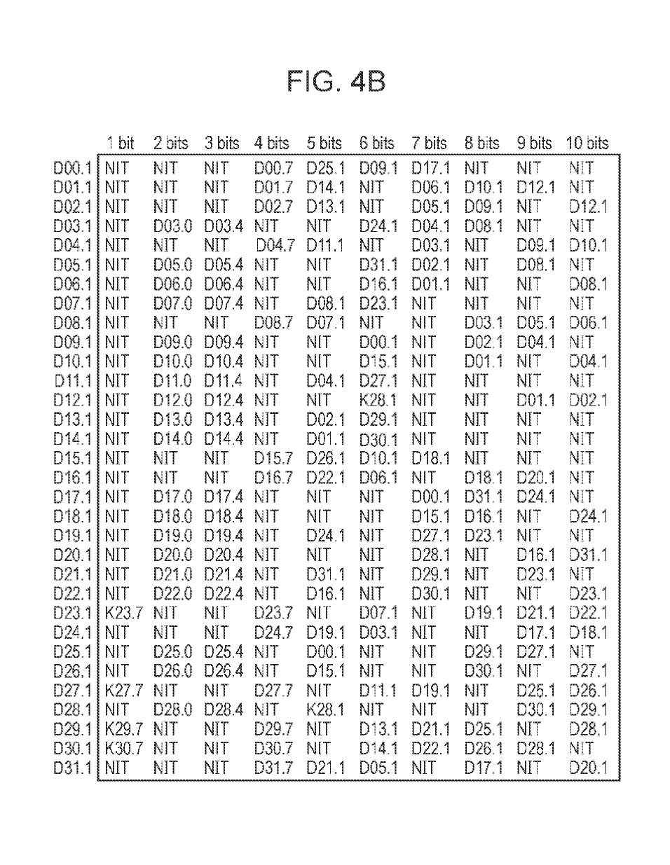

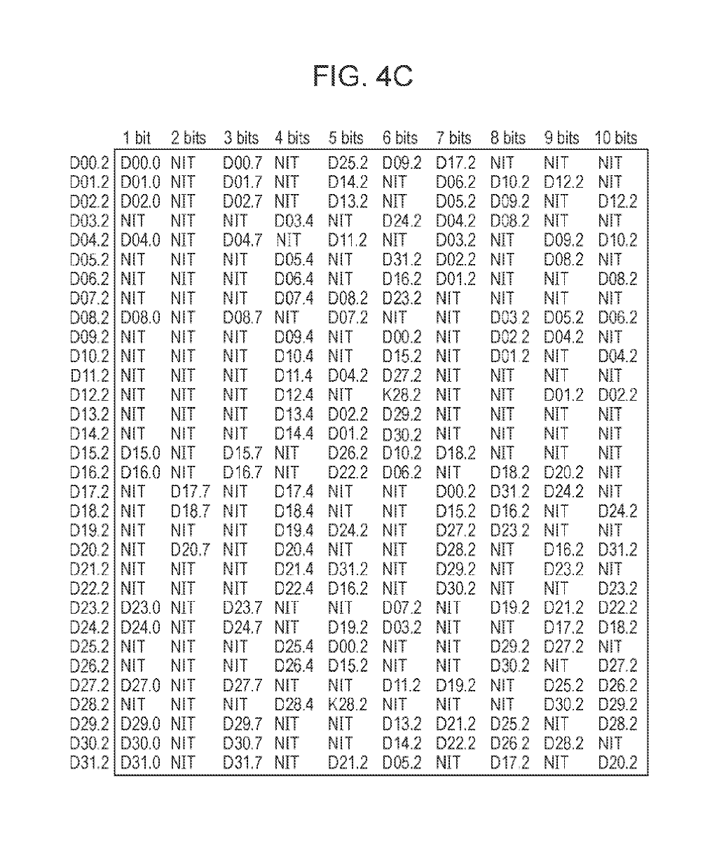

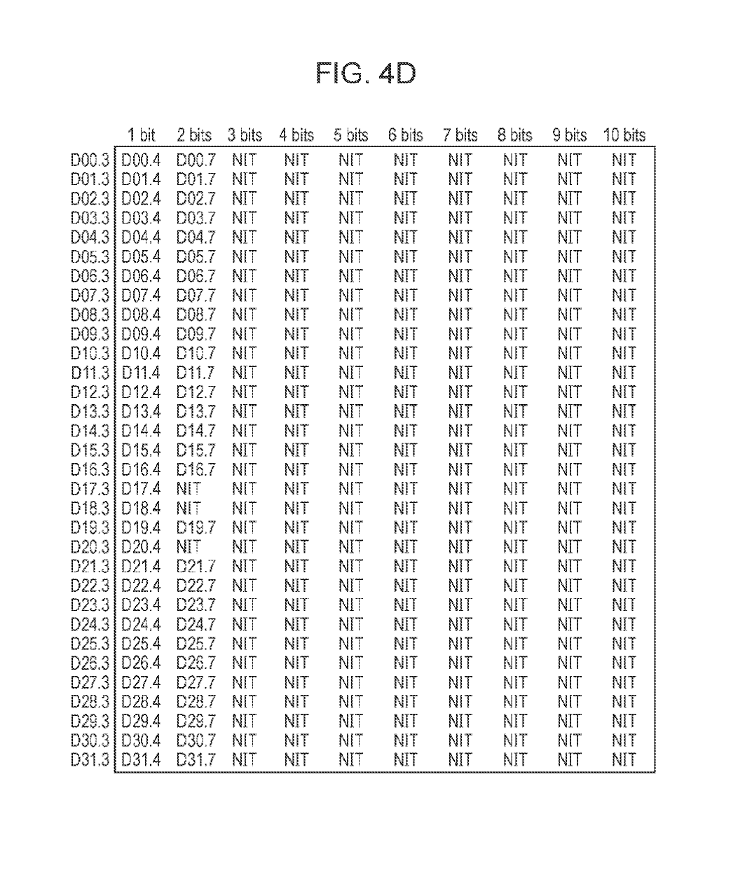

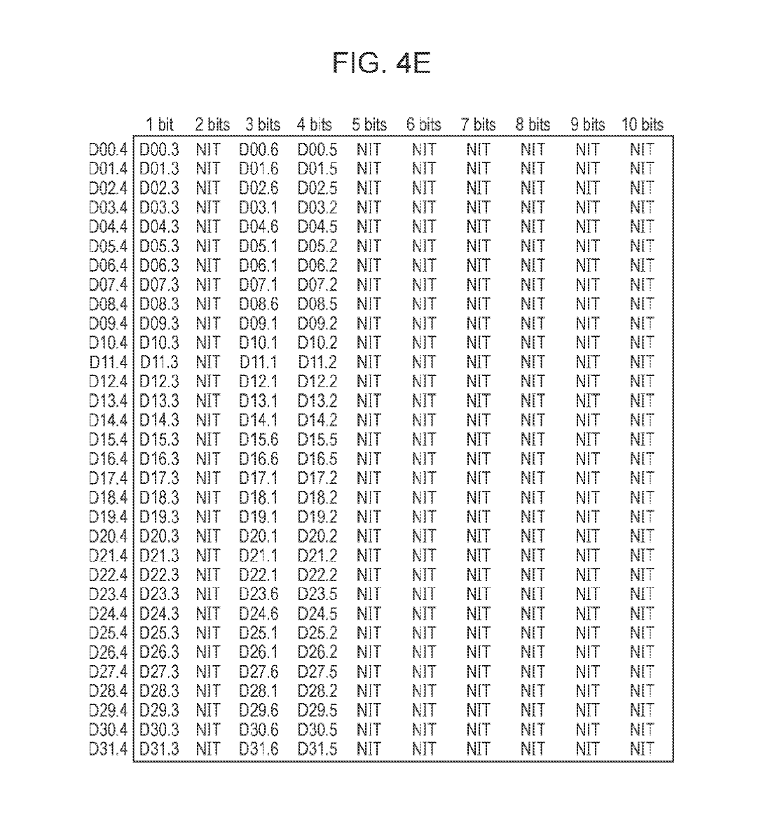

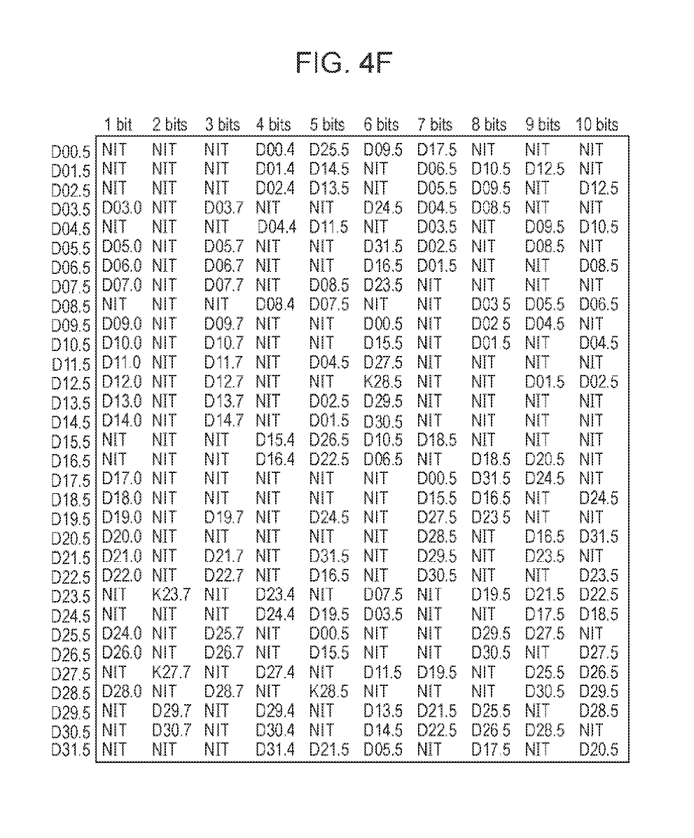

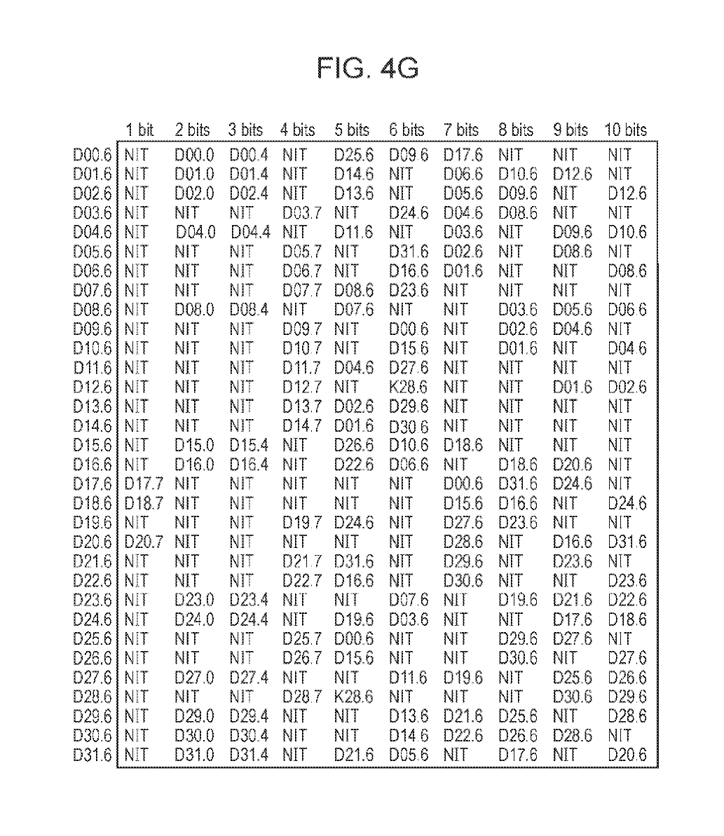

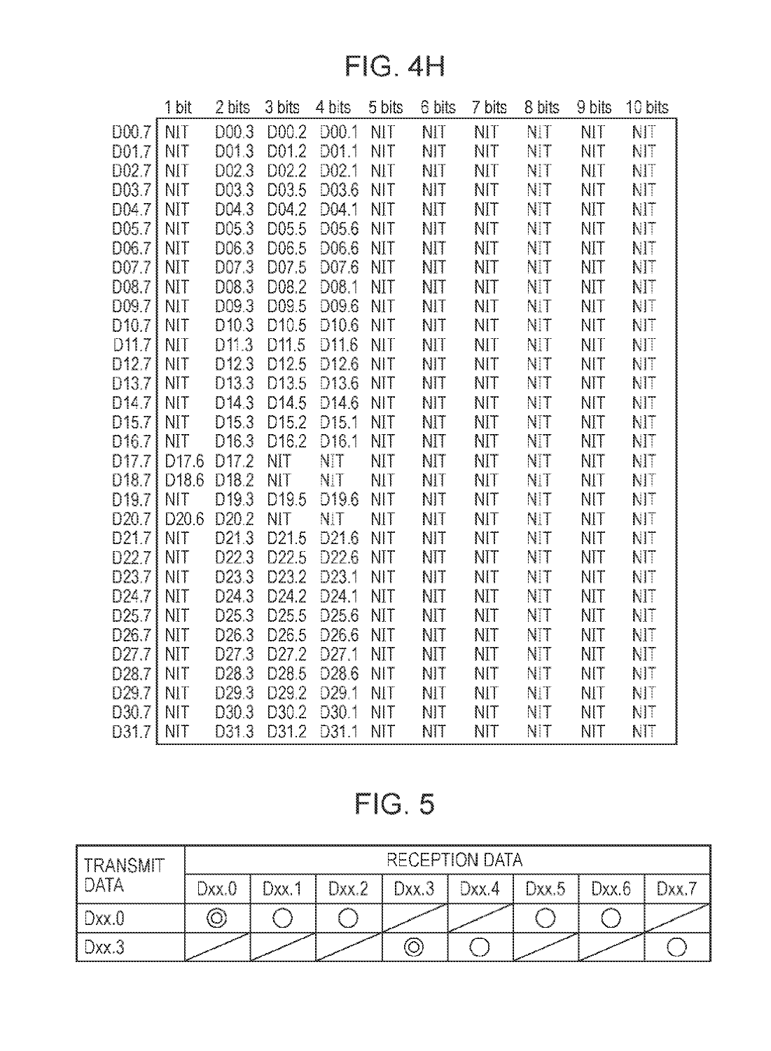

Next, error patterns will be described. In the case of transmitting data of 8 bits, the data are converted into data of 10 bits by an 8B10B conversion. There are 10 patterns of single-bit error which may occur to this 10-bit data. FIGS. 4A through 4H illustrate received data after 8B10B inverse conversion corresponding to 10 error patterns. In the drawings, D00.0 through D31.7 in the left column are transmission data before 8B10B conversion, and 1 bit through 10 bit indicate the position of the bit to which an error is occurred from the top. If data are Dxx.y, xx corresponds to the lower-order 5 bits of 0 through 31, and y corresponds to the higher-order 3 bits of 0 through 7. For example, in FIG. 4A, in the case where transmission data D00.0 are converted from 8 bits to 10 bits, if an error occurs to the first bit at the top, the data are converted to reception data D00.2. In the case where the transmission data D00.0 are converted from 8 bits to 10 bits, if an error occurs to the third bit from the top, no corresponding data are present on the conversion table, and therefore a not-in-table (NIT) error is caused. Among FIGS. 4A through 4H, in the FIGS. 4A, 4D, 4E, and 4H, if an error occurs in any of the 6th through 10th bits (the lower-order 5 bits), a not-in-table (NIT) error is caused.

In the case of Dxx.0 (see FIG. 4A), Dxx.3 (see FIG. 4D) Dxx.4 (see FIG. 4E), and Dxx.7 (see FIG. 4H), even if a single-bit error occurs, the lower-order 5 bits are correctly received. This indicates that transmission data illustrated in FIGS. 4A, 4D, 4E, and 4H may be used as the lower-order 5 bits of the transmission data. It is to be noted that, although FIGS. 4A through 4H illustrate the case where the running disparity (RD) is positive, the same applies to the case where the running disparity is negative.

FIG. 5 is a table showing the relationship between transmission data and reception data in the error patterns of FIGS. 4A and 4D. In FIG. 5, a double circle indicates that the reception data are correct, and a circle indicates that a single-bit error has occurred in the reception data. Among the above-mentioned Dxx.0, Dxx.3, Dxx.4, and Dxx.7 having lower-order 5 bits that are correctly received even if a single-bit error occurs, in the case where Dxx.0 is transmitted as transmission data, one of Dxx.0, Dxx.1, Dxx.2, Dxx.5, and Dxx.6 may be received as reception data as illustrated in FIG. 4A. In the case where Dxx.3 is transmitted as transmission data, one of Dxx.3, Dxx.4, and Dxx.7 may be received as reception data as illustrated in FIG. 4D, which are different from those which may be received in the case where Dxx.0 is transmitted.

Accordingly, in this exemplary embodiment, Dxx.0 and Dxx.3 are used as the identification information item 112 contained in the header 110 of the transmit packet 100. More specifically, when the data 120 are image information, Dxx.0 is used as the identification information item 112, and the data identification information 112a of the higher-order 3 bits are set to “000”. On the other hand, when the data 120 are information other than image information, Dxx.3 is used as the identification information item 112, and the data identification information 112a of the higher-order 3 bits are set to “011”. Accordingly, even if a single-bit error occurs in the data identification information 112a, it is possible to correct the error. Further, in the case where a single-bit error occurs in the lower-order 5 bits, i.e., the sequence ID 112b in the identification information item 112, a NIT error is caused. This prevents the sequence ID from being incorrectly recognized.

### Operations in First Exemplary Embodiment

Next, exemplary operations in the present exemplary embodiment will be described with reference to the flowcharts of FIGS. 6A and 6B. FIG. 6A illustrates exemplary operations of the second transmitting and receiving apparatus 4 in a normal mode, and FIG. 6B illustrates exemplary operations of the second transmitting and receiving apparatus 4 in a retransmission mode.

(1) Generation of Transmit Packet

The transmit packet generating unit 22 of the first transmitting and receiving apparatus 2 puts data 120 to be transmitted, which are output from the input and output controller 21, into a packet by adding a header 110. The 8B10B converters 221A and 221B perform an 8B10B conversion on the header 110 and the data 120 included in the packet, and the ECC generating units 222A and 222B perform an ECC operation on the 8B10B-converted data 120 so as to generate an ECC 130. Then, the transmit packet generating unit 22 generates transmit packet 100 which contains the header 110, the data 120, and the ECC 130.

The transmit packet generating unit 22 uses Dxx.y (xx: 0 through 31, y=0, 3) shown in FIGS. 4A and 4D as an identification information item 112, in which y represents the higher-order 3 bits corresponding to the data identification information 112a, and xx represents the lower-order 5 bits corresponding to the sequence ID 112b. When the data 120 are image information, y=0 is used. When the data 120 are information other than image information, y=3 is used. Accordingly, when the identification information item 112 that is converted from 8 bits to 10 bits by the 8B10B converters 221A and 221B is transmitted, even if an error occurs to any one bit among 10 bits, the sequence ID 112b of the lower-order 5 bits causes NIT indicating that the corresponding data are not present on the conversion table, or is received without any error. Further, the data identification information 112a of the higher-order 3 bits can be corrected or causes NIT if incorrectly received. The transmit packet generating unit 22 repeatedly uses D00.0 through D31.0 shown in FIG. 4A, and D00.3 through D31.3 shown in FIG. 4D.

(2) Transmission of Transmit Packet

The transmit packet 100 generated by the transmit packet generating unit 22 is converted from parallel data to serial data by the parallel-to-serial converters 23A and 23B, and is serially transmitted from the first transmitting and receiving apparatus 2 to the second transmitting and receiving apparatus 4 through the first lane 31 and the second lane 32, respectively, of the transmission path 3.

(3) Reception of Transmit Packet

The transmit packet 100 received by the second transmitting and receiving apparatus 4 is converted from the serial data to parallel data by the serial-to-parallel converters 41A and 41B, and is input to the error detecting unit 42.

(4) ECC Check

The ECC error detecting and correcting units 421A and 421B of the error detecting unit 42 perform an ECC check, and report the ECC check results to the retransmission request packet generating unit 44 (S1). If there is a single-bit ECC error, the ECC error detecting and correcting units 421A and 421B correct the single-bit ECC error (S2), and output the data to the 10B8B converters 422A and 422B, respectively. The 10B8B converters 422A and 422B perform an 8B10B inverse conversion on the data (S3), and output the data to the input and output controller 43 through the header error detecting and correcting units 423A and 423B, respectively. The data are stored in a memory (not shown) in the input and output controller 43 (S4).

If there is an ECC error of two or more bits in the ECC check of the above Step S1, the ECC error detecting and correcting units 421A and 421B cannot correct the ECC error, and therefore output the data to the 10B8B converters 422A and 422B, respectively. The 10B8B converters 422A and 422B perform an 8B10B inverse conversion on the data (S5), and output the data to the header error detecting and correcting units 423A and 423B, respectively.

(5) Header Check

The header error detecting and correcting units 423A and 423B perform a header check on the header 110, and report the header check results to the retransmission request packet generating unit 44 (S6). If there is no error in the header 110, the header error detecting and correcting units 423A and 423B determine whether the type of the data 120 is image information on the basis of the data identification information 112a (S7). If the data type is image information (S7: Yes), the data are output to the input and output controller 43. The data are stored in a memory (not shown) in the input and output controller 43 (S4). The reason why the same operations as those performed in the case where there is no ECC error are performed even if an ECC error of two or more bits is present is because, if the data are image information, one corrupted byte in the data only creates one pixel with incorrect information, which does not cause a problem.

If there is a single bit error (ID error) in the data identification information 112a (ID) in the header 110 in the header check of the above Step S6, the header error detecting and correcting units 423A and 423B correct the data identification information 112a (ID) using the table of FIG. 5 (S8), and determine whether the type of the data 120 is image information on the basis of the data identification information 112a (S9). If the data type is image information (S9: Yes), the data are output to the input and output controller 43. The data are stored in the memory (not shown) in the input and output controller 43 (S4).

(6) Retransmission Mode

If the type of the data 120 is not image information in the above Steps S7 and S9, the data 120 are discarded, and a NAK is returned so as to switch the mode to the retransmission mode (S10). Similarly, if a NIT error is detected in the header 110 in the header check of the above Step S6, the data are discarded, and a NAK is returned so as to switch the mode to the retransmission mode (S10). More specifically, the retransmission request packet generating unit 44 generates a retransmission request packet 200 that contains a start packet 210, a negative acknowledgement (NAK) 211a, and a sequence ID 211b, as illustrated in FIG. 3. The retransmission request packet 200 is subjected to an 8B10B conversion by the 8B10B converter 45, is converted from parallel data to serial data by the parallel-to-serial converter 46, and is transmitted to the first transmitting and receiving apparatus 2 through the third lane 33.

The retransmission request packet 200 transmitted from the first transmitting and receiving apparatus 2 is converted from serial data to parallel data by the serial-to-parallel converter 24, is subjected to a 10B8B conversion by the 10B8B converter 25, and is input to the retransmission controller 26.

An error detecting unit 261 of the retransmission controller 26 performs an error check on the response information item 211. If an error is detected, an error correcting unit 262 corrects the error. The transmission data shown in FIGS. 4A and 4D are used as a negative acknowledgement (NAK) 211a. Therefore, even if a single-bit error occurs in the negative acknowledgement (NAK) 211a, the negative acknowledgement (NAK) 211a can be corrected. The retransmission controller 26 instructs the input and output controller 21 to perform a retransmission.

The input and output controller 21 transmits data held in the transmission buffer for retransmission and corresponding to the sequence ID to the transmit packet generating unit 22. The transmit packet generating unit 22 generates a transmit packet 100 whose retransmission is instructed. The regenerated transmit packet 100 is parallel-to-serial converted, and then is transmitted to the second transmitting and receiving apparatus 4, in the manner described above.

As illustrated in FIG. 6B, as in the case of the flow of FIG. 6A, the second transmitting and receiving apparatus 4 performs an ECC check (S11), performs a single-bit error correction if there is a single-bit error (S12), and performs an 8B10B inverse conversion (S13). In the retransmission mode, an ID check of the header 110 is subsequently performed (S14), and then the data are stored in the memory (not shown) in the input and output controller 43 (S15).

In the ECC check of the above Step S11, if there is an ECC error of two or more bits, as in the case of the flow of FIG. 6A, the second transmitting and receiving apparatus 4 performs an 8B10B inverse conversion (S16), a header check (S17), and an ID correction (S19). If the type of the data 120 is image information, ID check (S14) is performed. If the type of the data 120 is information other than image information, the data 120 are discarded, and a NAK is returned (S21) so as to switch the mode to a retransmission repeat mode.

In the header check of the above Step S17, if there is a NIT error, a system failure is determined to be caused.

### Second Exemplary Embodiment

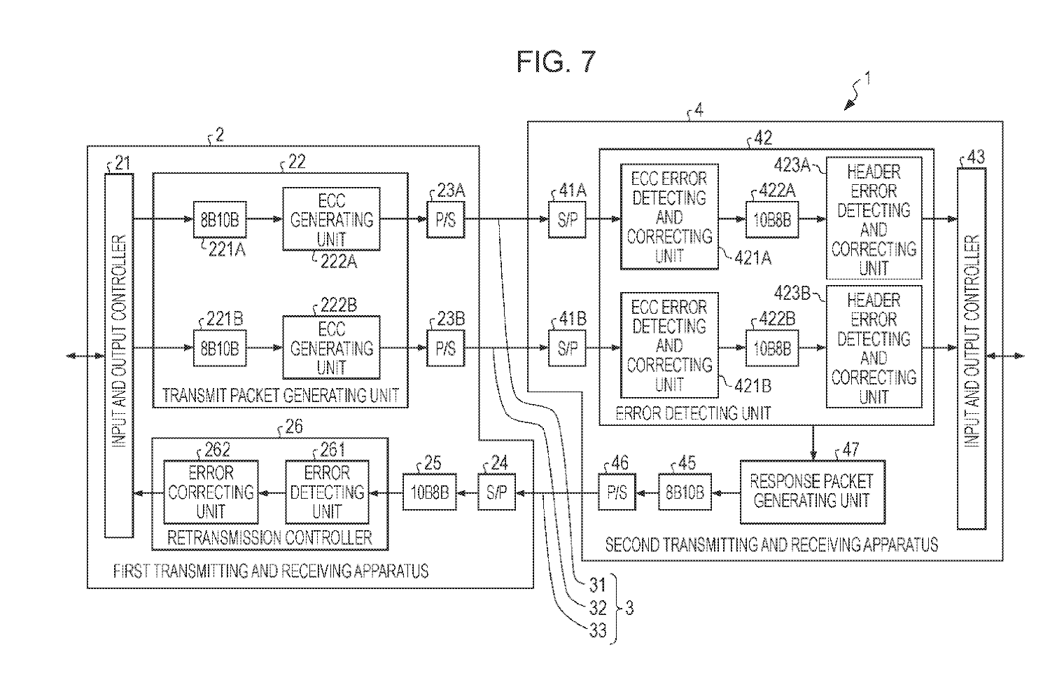

FIG. 7 is a block diagram showing an exemplary configuration of a transmitting and receiving system 1 according to a second exemplary embodiment of the present invention. The transmitting and receiving system 1 of this exemplary embodiment has the same configuration as that of the first exemplary embodiment, except that a second transmitting and receiving apparatus 4 includes a response packet generating unit 47.

More specifically, a first transmitting and receiving apparatus 2 of this exemplary embodiment includes an input and output controller 21, a transmit packet generating unit 22, parallel-to-serial converters (P/S) 23A and 23B, a serial-to-parallel converter (S/P) 24, a 10B8B converter (10B8B) 25, and a retransmission controller 26.

The second transmitting and receiving apparatus 4 includes serial-to-parallel converters (S/P) 41A and 41B, an error detecting unit 42, an input and output controller 43, an 8B10B converter (8B10B) 45, a parallel-to-serial converter (P/S) 46, and a response packet generating unit 47. The response packet generating unit 47 is an example of a generating unit.

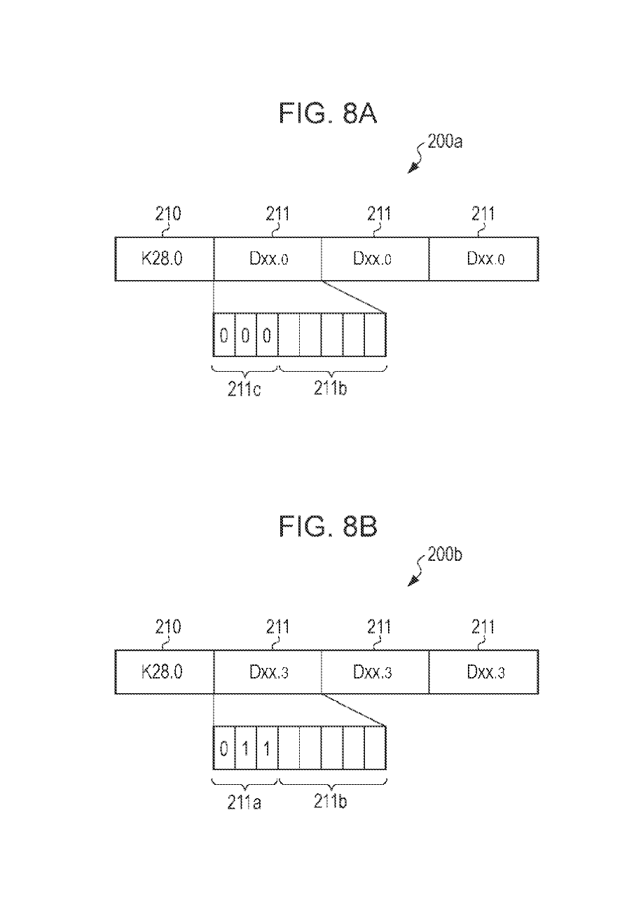

FIGS. 8A and 8B illustrate exemplary configurations of response packets generated by the response packet generating unit 47 of the second transmitting and receiving apparatus 4, wherein FIG. 8A illustrates a positive acknowledgement (ACK) and FIG. 8B illustrates a negative acknowledgement (NAK).

As shown in FIG. 8A, an ACK response packet 200a includes a start packet 210 including, for example, K28.0, and plural (e.g., three) response information items 211. Each response information item 211 includes a positive acknowledgement (ACK) 211c of the higher-order 3 bits, and a sequence ID 211b of the lower-order 5 bits for identifying the first lane 31, the second lane 32, and the transmit packet 100. As the response information item 211 of the ACK response packet 200a, a code that makes it possible to distinguish between an positive acknowledgement (ACK) and a negative acknowledgement (NAK) even in the case where a single-bit error due to transmission occurs during transmission of the ACK response packet 200a to the first transmitting and receiving apparatus 2 is used. For example, Dxx.0 may be used. With this configuration, the second transmitting and receiving apparatus 4 transmits the response information item 211 three times. It is to be noted that the number of response information items 211 included in the ACK response packet 200a is not limited to three.

As shown in FIG. 8B, a NAK response packet 200b includes a start packet 210 including, for example, K28.0, and plural (e.g., three) response information items 211. Each response information item 211 includes a negative acknowledgement (NAK) 211a of the higher-order 3 bits, and a sequence ID 211b of the lower-order 5 bits for identifying the lanes 31 and 32 and the transmit packet 100. As the response information item 211 of the NAK response packet 200b, a code that makes it possible to distinguish between an positive acknowledgement (ACK) and a negative acknowledgement (NAK) even in the case where a single-bit error due to transmission occurs during transmission of the NAK response packet 200b to the first transmitting and receiving apparatus 2 is used. For example, Dxx.3 may be used. With this configuration, the second transmitting and receiving apparatus 4 transmits the response information item 211 three times. It is possible to determine in which of the lanes 31 and 32 and to which transmit packet 100 an error has occurred, on the basis of the negative acknowledgement (NAK) 211a and the sequence ID 211b. It is to be noted that Dxx.3 may be used for the response information item 211 of the ACK response packet 200a, and Dxx.0 may be used for the response information item 211 of the NAK response packet 200b. The number of response information items 211 included in the NAK response packet 200b is not limited to three.

### Third Exemplary Embodiment

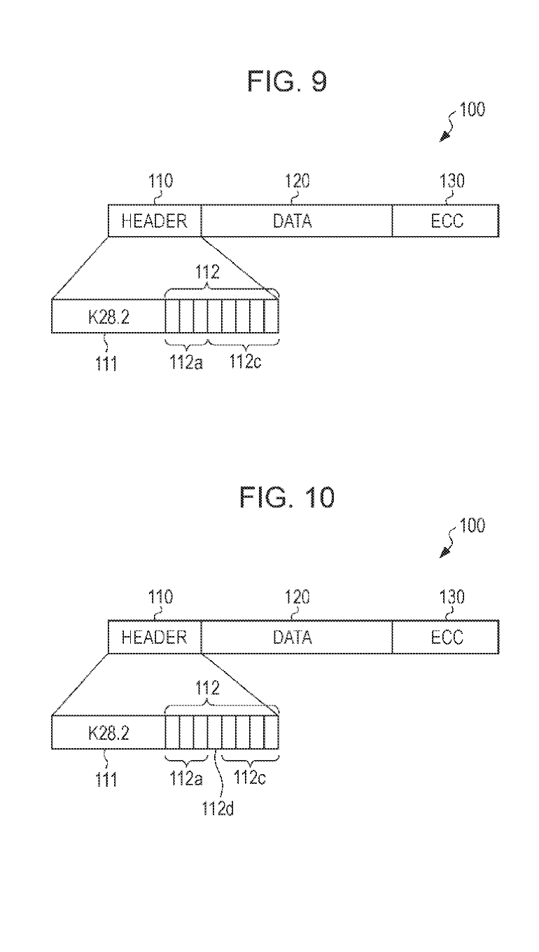

FIG. 9 is a diagram illustrating an exemplary configuration of a transmit packet 100 generated by a transmit packet generating unit of a transmitting and receiving system according to a third exemplary embodiment of the present invention.

A transmit packet 100 of this exemplary embodiment contains a header 110, data 120, and an ECC 130 in the same manner as that of the first exemplary embodiment, but differs from that of the first exemplary embodiment in the configuration of an identification information item 112 of the header 110. More specifically, the identification information item 112 includes data identification information 112a of 3 bits for identifying whether the data 120 are image information or information other than image information, and color information 112c of 5 bits indicating color information of the data 120 representing image information. As for the color information 112c, “00001” may represent yellow; “00010” may represent magenta; “00100” may represent cyan; “01000” may represent black; and “10000” may represent a special color. It is to be noted that the relationship between the code of 5 bits and the color is not limited thereto.

### Fourth Exemplary Embodiment

FIG. 10 is a diagram illustrating an exemplary configuration of a transmit packet 100 generated by a transmit packet generating unit of a transmitting and receiving system according to a fourth exemplary embodiment of the present invention.

A transmit packet 100 of this exemplary embodiment contains a header 110, data 120, and an ECC 130 in the same manner as that of the first exemplary embodiment, but differs from that of the first exemplary embodiment in the configuration of an identification information item 112 of the header 110. More specifically, the identification information item 112 includes data identification information 112a of 3 bits for identifying whether the data 120 are image information or information other than image information, monochrome/color identification information 112d of 1 bit indicating whether the data 120 representing image information are in a monochrome mode or a color mode, and color information 112c of 4 bits indicating color information of the data 120 representing image information. As for the monochrome/color identification information 112d and the color information 112c, “10000” may represent the monochrome mode; “00001” may represent yellow in the color mode; “00010” may represent magenta in the color mode; “00100” may represent cyan in the color mode; and “01000” may represent black in the color mode. It is to be noted that the relationship between the code of 5 bits and the color is not limited thereto.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art.

Further, part of the elements of the above exemplary embodiments may be omitted, and steps in the flows of the above exemplary embodiments may be added, deleted, modified, or rearranged, without departing from the scope of the present invention. Furthermore, programs used in the above exemplary embodiments may be stored and provided in a recording medium such as a CD-ROM.

What is claimed is:

1. A transmitting and receiving system comprising:
a first transmitting and receiving apparatus including
a generating unit that generates a transmission packet by attaching an error correction code to data to be transmitted, the data being subjected to a bit number conversion, wherein a code that detects or corrects, in the case where a single-bit error occurs, the single-bit error is used as information bits contained in a header of the transmission packet, the code being used when a bit error uncorrectable by the error correction code occurs due to transmission during transmission of the transmission packet, and
a transmitting unit that transmits the transmission packet.

2. The transmitting and receiving system according to claim 1, further comprising:
a second transmitting and receiving apparatus including
a receiving unit that receives the transmission packet transmitted from the transmitting unit of the first transmitting and receiving apparatus, and
a correcting unit that detects and corrects an error in the information bits contained in the header of the transmission packet that is received by the receiving unit.

3. The transmitting and receiving system according to claim 1, wherein the information bits contained in the header include data identification information that indicates a type of the data to be transmitted.

4. The transmitting and receiving system according to claim 1, wherein the information bits contained in the header include data identification information that indicates a type of the data to be transmitted, and identification information that identifies the transmission packet.

5. The transmitting and receiving system according to claim 1, wherein the information bits contained in the header include data identification information that indicates a type of the data to be transmitted, and color information.

6. The transmitting and receiving system according to claim 2, wherein the second transmitting and receiving apparatus further includes
a generating unit that generates a response packet as a response result with respect to the transmission packet, wherein a code that detects and corrects, in the case where a single-bit error occurs due to transmission during transmission of the response packet, the single-bit error is used.

7. A transmitting and receiving method comprising:
generating, by a first transmitting and receiving apparatus, a transmission packet by attaching an error correction code to data to be transmitted, the data being subjected to a bit number conversion, wherein a code that detects or corrects, in the case where a single-bit error occurs, the single-bit error is used as information bits contained in a header of the transmission packet, the code being used when a bit error uncorrectable by the error correction code occurs due to transmission during transmission of the transmission packet;
transmitting, by the first transmitting and receiving apparatus, the transmission packet;
receiving, by a second transmitting and receiving apparatus, the transmission packet transmitted in the transmitting; and
detecting and correcting, by the second transmitting and receiving apparatus, an error in the information bits contained in the header of the transmission packet that is received in the receiving.

8. A non-transitory computer readable medium storing a program for causing
a computer of a first transmitting and receiving apparatus to function as
a generating unit that generates a transmission packet by attaching an error correction code to data to be transmitted, the data being subjected to a bit number conversion, wherein a code that detects or corrects, in the case where a single-bit error occurs, the single-bit error is used as information bits contained in a header of the transmission packet, the code being used when a bit error uncorrectable by the error correction code occurs due to transmission during transmission of the transmission packet, and
a transmitting unit that transmits the transmission packet; and
a computer of a second transmitting and receiving apparatus to function as
a receiving unit that receives the transmission packet transmitted from the transmitting unit of the first transmitting and receiving apparatus, and
a correcting unit that detects and corrects an error in the information bits contained in the header of the transmission packet that is received by the receiving unit.
